(19) United States
(12) Patent Application Publication
(10) Pub. No.: US 2008/0124858 A1
(43) Pub. Date: May 29, 2008

(54) SELECTIVE STRESS RELAXATION BY AMORPHIZING IMPLANT IN STRAINED SILICON ON INSULATOR INTEGRATED CIRCUIT

(76) Inventors: Bich-Yen Nguyen, Austin, TX (US); Voon-Yew Thean, Austin, TX (US)

Correspondence Address: FREESCALE SEMICONDUCTOR, INC., 770 W PARMER LANE, MDTX32/PLO2, AUSTIN, TX, 78729, US

(21) Appl. No.: 11/462,773

(22) Filed: Aug. 7, 2006

(51) Int. Cl. H01L 21/8238

(52) U.S. Cl. 438/217; 257/E21.633

(57) ABSTRACT

A semiconductor fabrication process includes forming an NMOS gate electrode overlying a biaxially strained NMOS active region and forming a PMOS gate electrode overlying a biaxially strained PMOS active region. Amorphous silicon is created in a PMOS source/drain region to reduce PMOS channel direction tensile stress. A PMOS source/drain implant is performed in the amorphous PMOS source/drain. Creating amorphous silicon in the PMOS source/drain may include implanting an electrically neutral species (e.g., Ge, Ga, or Xe). The wafer then may be annealed and a second PMOS amorphizing implant performed. PMOS halo, source/drain extension, and deep source/drain implants may then be performed. Following the first amorphizing implant, a sacrificial compressive stressor may be formed over the PMOS region, the wafer annealed to recrystallize the amorphous PMOS region, and the compressive stressor removed. NMOS source/drain implants may be performed without a preceding amorphizing implant or with a low energy amorphizing implant.

### FIELD OF THE INVENTION

The invention is in the field of semiconductor fabrication and integrated circuits and, more specifically, fabrication processes and integrated circuits that employ strained silicon.

### RELATED ART

In the field of integrated circuits, strained silicon refers generally to the practice of intentionally stressing the channels of NMOS and/or PMOS transistors to improve carrier mobility. Biaxially-strained substrates including, but not limited to, Strained-Silicon on Insulator substrates, provide high levels of strain directly in the channel of the devices fabricated on these substrates. This is in contrast to typical process-induced stressors which introduce strain remotely through the addition of stressed materials adjacent or in close proximity to the channel in order to induce a strained channel. However, simultaneously improving the carrier mobility for both types of devices is difficult with a uniformly-strained substrate because PMOS carrier mobility and NMOS carrier mobility are optimized under different types of strain. Moreover, strain conditions that optimize carrier mobility may negatively impact other device characteristics such as threshold voltage, thereby complicating the selection of strain conditions. It would be desirable to implement a fabrication process and design for devices fabricated on biaxially-strained substrate in which NMOS and PMOS carrier mobility is simultaneously optimized without negatively affecting other device characteristics.

### BRIEF DESCRIPTION OF THE DRAWINGS

The present invention is illustrated by way of example and not limited by the accompanying figures, in which like references indicate similar elements, and in which:

FIG. 1 is a partial cross sectional view of a semiconductor wafer at an intermediate stage in the fabrication of an integrated circuit according to the present invention in which an NMOS and a PMOS transistor both experience tensile stress;

FIG. 2 depicts processing subsequent to FIG. 1 in which the PMOS transistor is subjected to a stress relief implant to amorphize the PMOS source/drain regions;

FIG. 3 depicts processing subsequent to FIG. 2 in which the wafer is annealed to recrystallize the PMOS source/drain regions emphasizing the reduction or elimination of the tensile stress in the PMOS device;

FIG. 4 is a top view of the wafer of FIG. 3 illustrating the channel stress components of the NMOS and PMOS devices;

FIG. 5 depicts processing subsequent to FIG. 3 in which the PMOS device is subjected to a source/drain amorphizing implant;

FIG. 6 depicts processing subsequent to FIG. 5 in which PMOS halo and extension implants have been performed;

FIG. 7 depicts processing subsequent to FIG. 6 in which NMOS halo and extension implants have been performed;

FIG. 8 depicts processing subsequent to FIG. 7 following spacer formation, NMOS and PMOS source/drain implants, and formation of interlevel dielectric layers over the NMOS and PMOS devices;

FIG. 9 depicts optional processing subsequent to FIG. 2 in which a thin oxide layer is formed over the PMOS device;

FIG. 10 depicts processing subsequent to FIG. 9 in which a compressive dielectric layer is formed over the PMOS device to create compressive strain in the PMOS device;

FIG. 11 depicts processing subsequent to FIG. 10 in which the wafer is annealed to recrystallize the PMOS source/drain regions; and

FIG. 12 depicts processing subsequent to FIG. 11 in which the compressive dielectric layer is removed illustrating the presence of compressive stress in the PMOS device after removal of the compressive dielectric layer.

Skilled artisans appreciate that elements in the figures are illustrated for simplicity and clarity and have not necessarily been drawn to scale. For example, the dimensions of some of the elements in the figures may be exaggerated relative to other elements to help improve the understanding of the embodiments of the present invention.

### DETAILED DESCRIPTION OF THE DRAWINGS

In one aspect, an integrated circuit fabrication process includes forming an NMOS transistor and a PMOS transistor on biaxially strained semiconductor on insulator (SOI) active regions, in which a channel direction stress component in the PMOS transistor has been made less tensile or possibly made compressive to maximize carrier mobility in both transistors. In one embodiment, the NMOS and PMOS transistors both exhibit inherent biaxial tensile stress following gate electrode formation. A PMOS source/drain region is then amorphized with an implant process. The wafer may then be annealed to recrystallize the amorphous PMOS source/drain region. The re-crystallized source/drain region exhibit little or no tensile stress. The amorphization and thermal re-crystallization process in the source-drain causes the adjacent channel region under the gate electrode to be less tensile. A second PMOS amorphizing implant or PMOS source/drain optimizing implant may then be performed followed by halo and source/drain extension implants in the re-amorphized PMOS source/drain regions. NMOS halo and extension implants may also be performed selectively in the NMOS regions without a preceding NMOS source/drain amophizing implant or with a very low energy NMOS amorphizing implant. Conventional NMOS and PMOS spacers and deep source/drain regions may then be formed followed by the formation of stressors over the NMOS and PMOS transistors where the stressor overlying the NMOS region preferably imparts tensile or no stress on the NMOS active region and the ILD (interlevel dielectric) over the PMOS transistor preferably imparts compressive stress on the PMOS active region.

The PMOS processing may further include forming a sacrificial compressive stressor over the PMOS region after the first amorphizing PMOS implant. A re-crystallization anneal is performed with the sacrificial stressor in place followed by a removal of the sacrificial stressor.

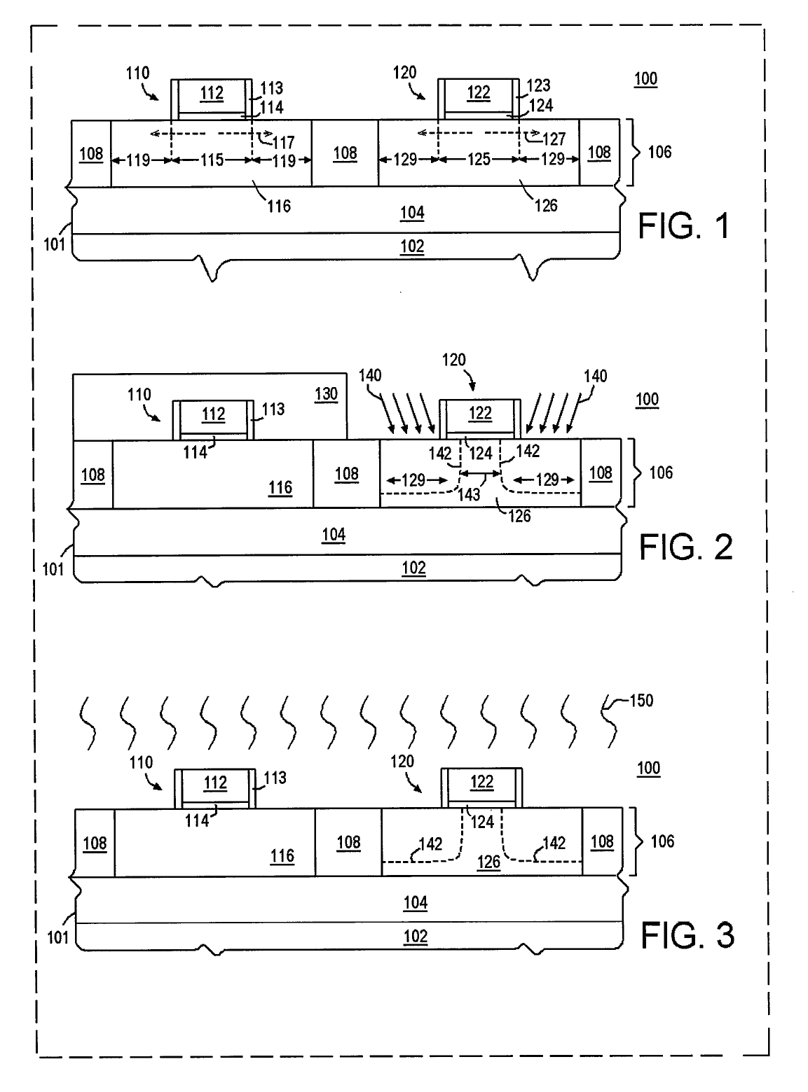

Turning now to FIG. 1, a first in a series of partial cross sectional views of a semiconductor wafer 101 at various stages in the formation of an integrated circuit 100 is shown. Integrated circuit wafer 101 as depicted in FIG. 1 is a semiconductor on insulator (SOI) wafer that includes a buried oxide (BOX) layer 104 overlying a bulk substrate 102, which is preferably a semiconductor material such as silicon or a semiconductor compound such as gallium arsenide. An active layer 106 of wafer 101 overlies BOX layer 104. Active layer 106 includes an NMOS active region 116, a PMOS active region 126, and isolation structures 108 that provide physical and electrical isolation between active regions 116 and 126. More specifically, as referred to below, the semiconductor of active regions 116 and 126 is referred to as exhibiting biaxial stress meaning stress in the plane of cross section and stress in a plane that is perpendicular to the plane of cross section. In the embodiment described in the drawings, the active regions are under biaxial tensile stress at the point of the processing sequence depicted in FIG. 1. The described processing sequence is suitable to alleviate the tensile stress in one the channel direction of the PMOS active region 126.

At the stage depicted in FIG. 1, integrated circuit 100 is partially complete. More specifically, a gate electrode 112 of NMOS transistor 110 and a gate electrode 122 of PMOS transistor 120 have been formed over active regions 116 and 126 respectively. A gate dielectric layer 114 has been formed between NMOS gate electrode 112 and NMOS active region 116. A gate dielectric 124 has been formed between PMOS gate electrode 122 and PMOS active region 126. Gate dielectrics 114 and 124 may be formed from a common film such as a thermally formed silicon dioxide film. Alternatively, NMOS gate dielectric 114 may be of a different material than PMOS gate dielectric 124. Gate dielectrics 114 and 124 may, for example, both be high-k dielectric materials, which are dielectric materials having a dielectric constant that is greater than the dielectric constant of silicon dioxide. As depicted in FIG. 1, relatively thin offset spacers 113 have been formed on sidewalls of NMOS gate electrode 112 and PMOS gate electrode 122. Offset spacers 113 are preferably a dielectric material such as silicon oxide or silicon nitride. The lateral boundaries of NMOS gate electrode 112 define approximate boundaries for an NMOS transistor channel region 115 and NMOS source/drain regions 119 in NMOS active region 116. Similarly, the lateral boundaries of PMOS gate electrode 122 define approximate boundaries for an PMOS transistor channel region 125 and PMOS source/drain regions 129 in NMOS active region 126.

As depicted in FIG. 1, NMOS active region 116 and PMOS active region are both exhibiting tensile stress indicated by stress vectors 117 and 127 respectively. Stress vectors 117 and 127 represent stress in a direction referred to herein as the channel direction because it coincides with the direction that carriers move across the channel under conventional biasing conditions (e.g., the gate voltage substantially greater than the threshold voltage and the source and drain electrodes biased to ground and Vcc where Vcc is the voltage supplied by a power supply. Moreover, although not visible in the cross section view of FIG. 1, active regions 116 and 126 are under tensile stress in a direction perpendicular to the cross sectional plane. For purposes of improving carrier mobility, this biaxial tensile stress in the first channel region beneficially improves carrier mobility, but may result in an decrease in threshold voltage that might require an additional implant to adjust the Vt or the use of a gate electrode fabricated from a material that provides an appropriate work-function. Of course additional implants would tend to lower the carrier mobility.

In one aspect, one or more ion implantation processes may be performed to amorphize the substrate selectively. As depicted in FIG. 2, for example, a photoresist mask 130 is formed overlying the NMOS active region 116 and a first PMOS amorphizing implant 140, also referred to herein as a PMOS strain-relief amorphizing implant (SRAI) is performed. SRAI 140 preferably has sufficient energy and dose, and preferably has a sufficiently large or heavy implant species to amorphize a portion of PMOS active region 126. The amorphized PMOS active region is represented by the dashed lines 142. In some embodiments, PMOS amorphizing implant is performed with an inert or otherwise electrically neutral implant species such as Xe, Ge, and/or Ga. In these embodiments, SRAI 140 may be performed with an implant energy of approximately 40 keV and a dose of approximately 1×10¹⁵ cm⁻². The implant energy should be varied base on the thickness of source/drain region 129 such that almost all of region 129 is amorphized, leaving only minimal but sufficient undamaged semiconductor material above the buried dielectric 104 to serve as a crystal template for the subsequent thermal recrystallization process. As seen in FIG. 1, amorphous PMOS region 142 preferably extends from an upper surface of wafer 101 to a depth that is proximal to the BOX interface. A thickness of the undamaged source/drain crystal remaining above the buried oxide after SRAI 140 is preferably in the range of approximately 5 to 20 nm. Because SRAI 140 is performed with PMOS gate electrode 122 serving as an implant mask, a gap 143 underlying PMOS gate electrode 122 exists between amorphous PMOS regions 142 laterally displaced on either side of gate electrode 122 so that amorphous PMOS regions 142 is confined primarily to source/drain regions 129 of PMOS active regions 126. SRAI 140 may be an angled implant or un-angled (i.e., performed perpendicular to an upper surface of wafer 101) to control the dimension of gap 143. In the case of an angled implant, the angle of implant is preferably in the range of 0° to 30°. In the case of an angled implant, SRAI 140 may include two or more implants repeated with wafer 101 rotated between each implant. The effectiveness of SRAI 140 can be adjusted by varying implant parameters including implant angle, energy, and dose as well as the dimension of gate electrode 122. Maximal strain relaxation of channel region 125 can be achieved by angling SRAI 140 to minimize the dimension of gap 143 and maximize the amorphous region 142.

If SRAI 140 is sufficient for source/drain dopant channeling control and activation, PMOS source/drain implants (not depicted) may be performed following PMOS amorphizing implant 140. Alternatively, as depicted in FIG. 3, photoresist mask 130 is removed and an anneal 150 performed. Anneal 150 is preferably a neutral ambient anneal that can be either a low-temperature/long duration anneal (e.g., 700° C. for 30 minutes), a several-second long high-temperature spike anneal (e.g., a 1067-1070° C. spike) or an ultra-short millisecond-long anneal like laser or flash anneal, or any combination of the above. Thermal anneal 150 re-crystallizes the amorphous silicon in region 142 and relaxes the channel direction tensile stress component in PMOS active region 126. Depending on the thickness of NMOS region 116, the temperature and duration of the thermal annealing is optimized such that the desired biaxial strain in NMOS region 116 is maximally preserved.

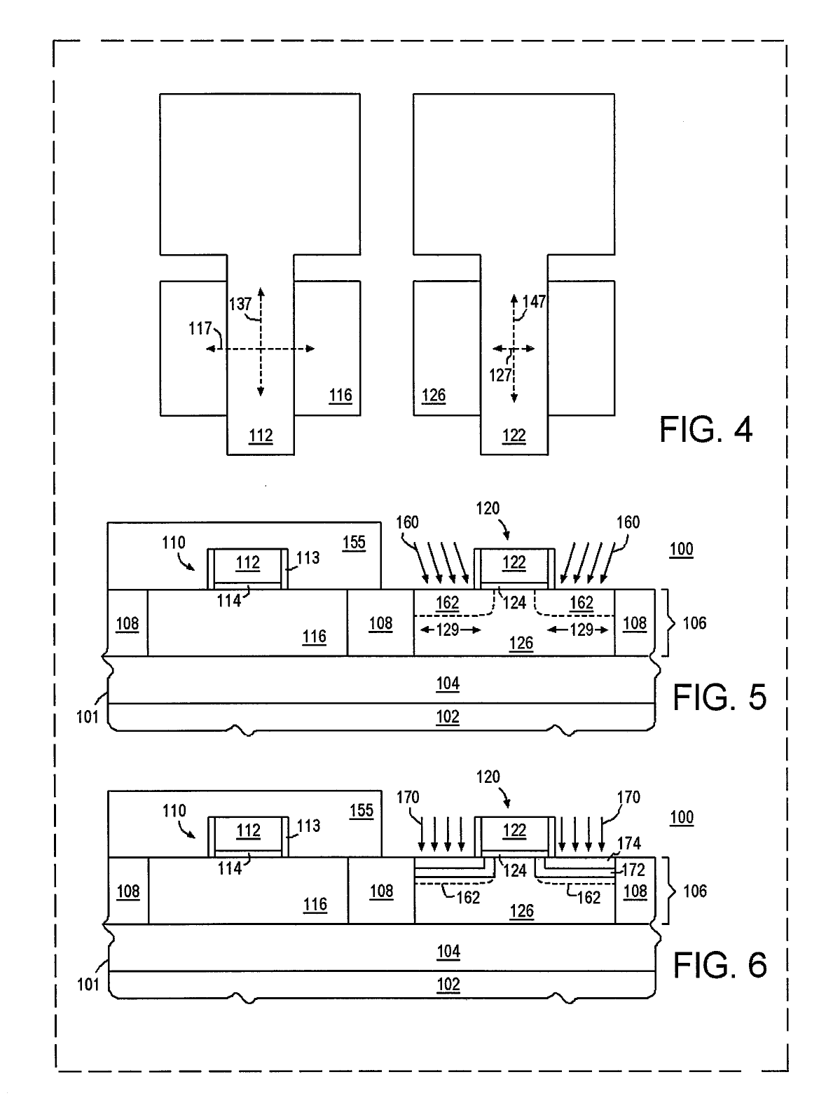

As depicted in the top view of FIG. 4, amorphizing implant 140 causes relaxation of the undesirable, PMOS channel direction stress 127 while preserving the desirable PMOS width direction stress component 147. In this manner, amorphizing implant 140 achieves uniaxial relaxation of a strained silicon on insulator starting material in the PMOS regions without affecting the desirable channel direction and width direction stress components 117 and 137 in the biaxially strained NMOS regions.

In FIG. 5, NMOS silicon active region 116 is re-masked with a photoresist mask 155 and a second PMOS amorphizing implant 160 is performed to re-amorphize a portion of PMOS source/drain regions 129. Second PMOS amorphizing implant 160 produces amorphous PMOS source/drain regions 162. Amorphizing PMOS source/drain regions 116 optimizes the regions for receiving a source/drain implant. In one embodiment, second PMOS amorphizing implant 160 uses an implant energy range of approximately 5-30 keV and a dose range of approximately 1×10¹⁶ and a suitably large implant species, for example, Xe, Ge, or Ga. Second PMOS amorphizing implant 160 may be an angled implant employing a wafer tilt in the range of 0° to 30° and may include multiple separate implants performed at various rotational positions of wafer 101. The second PMOS amorphizing implant 160 is an optional implant and it's angle, energy, and dose are adjusted to optimize the source/drain dopant implants that follow.

Referring to FIG. 6, one or more PMOS source/drain implants, collectively represented by reference numeral 170, are performed. In one embodiment, implant(s) 170 are performed immediately following second PMOS amorphizing implant 160 using the same photoresist mask 155 to mask NMOS regions 116. PMOS source/drain implants 170 may include a PMOS halo implant that uses an n-type implant species (e.g., Ar or P) to form an n-type PMOS halo region 172 and a PMOS extension implant that uses a p-type implant species (e.g., B or BF₂) to form PMOS source/drain extension regions 174 according to well known semiconductor fabrication processing. Following completion of implants 170, photoresist mask is removed and a short thermal anneal may be performed to activate and shape PMOS dopant profiles in the source/drain extension regions 174.

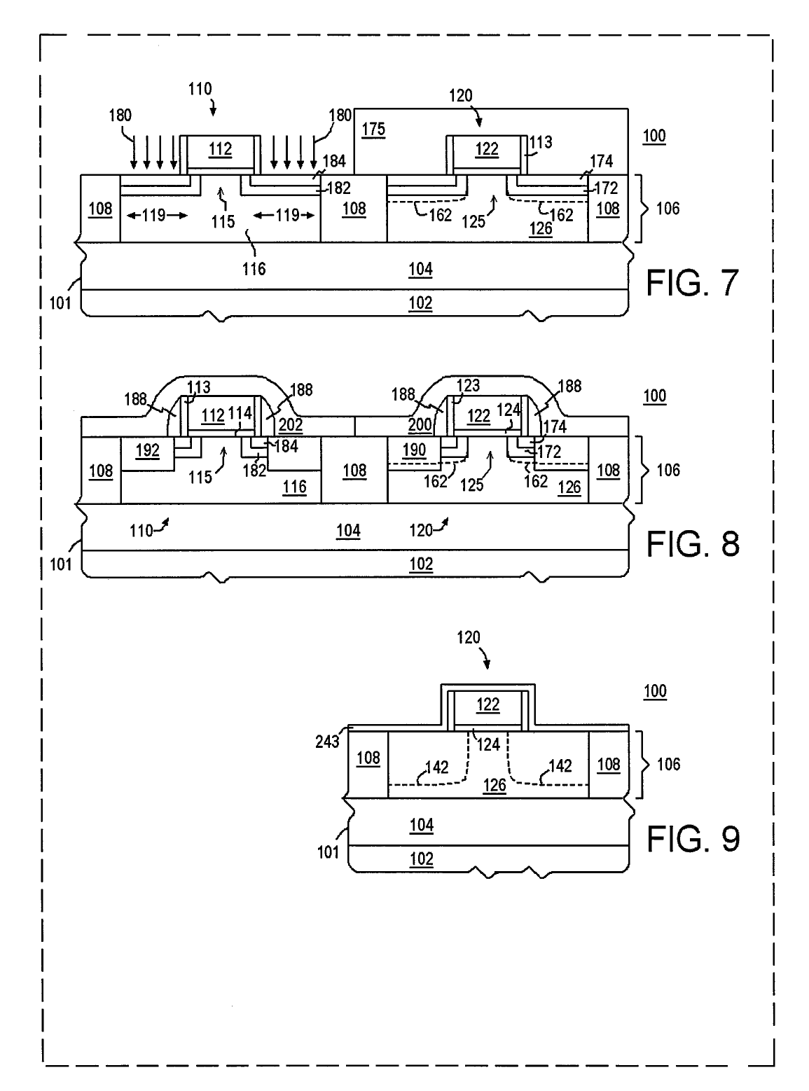

Referring to FIG. 7, photoresist mask 155 (from FIG. 6) has been removed and a photoresist mask 175 has been formed overlying PMOS active region 126. Thereafter, one or more NMOS implants collectively represented by reference numeral 180 are performed. In one embodiment, NMOS implants 180 include NMOS halo and source/drain extension implants that produce p-type NMOS halo regions 182 and n-type NMOS source/drain extension regions 184 in NMOS source/drain regions 119 laterally disposed on either side of NMOS channel region 115 underlying NMOS gate electrode 112. In some embodiments, NMOS halo and source/drain extension implants 180 are performed immediately following formation of photoresist mask 175 without an intervening NMOS amorphizing implant. In these embodiments, NMOS active region 116 is in a crystalline state during NMOS implants 180. In another embodiment, NMOS implants 180 may include or be preceded by a very shallow NMOS PAI, for example, having an implant energy of no more than 20 keV) to minimize damage to the NMOS strained SOI source/drain regions. In other words the inherently biaxial strain of the SSOI starting material is maintained in the NMOS regions because biaxial tensile stress beneficially improves NMOS carrier mobility.

In FIG. 8, extension spacers 188 are formed adjacent sidewalls of gate electrodes 112 and 122 and, in the depicted implementation, in contact with sidewalls of offset spacers 113 and 123 in a conventional manner preferably using a chemical vapor deposition (CVD) silicon nitride or other suitable electrical insulator. Following the formation of extension spacers 188, an NMOS deep implant is performed to produce NMOS source/drain structures 192 in NMOS active region 116 laterally disposed on either side of NMOS channel region 115 and self aligned (with some small overlap) to extension spacers 188. Similarly, a PMOS deep implant is performed to produce PMOS source/drain structures 190 in PMOS active region 126 laterally disposed on either side of PMOS channel region 125 and self aligned (with some small overlap) to extension spacers 188. The deep source/drain processing sequence is an implementation detail and no specific deep source/drain processing sequence is mandated by this disclosure.

As depicted in FIG. 8, a PMOS stressor 200 and an NMOS stressor 202 are formed overlying PMOS transistor 120 and NMOS transistor 110 respectively. In one embodiment, stressors 200 and 202 may be a dielectric material including, as an example, silicon nitride. The stress effects of PMOS stressor 120 are preferably different than the stress effects of NMOS stressor 110. Specifically, it is preferable if PMOS stressors 200 is a compressive stressors that imparts compressive stress to PMOS active region 126. Is also desirable if NMOS stressor 202 imparts either no net stress on NMOS active region 116 or a relatively small amount of tensile stress on NMOS active region 115. The compressive effect of PMOS stressor 200 may result in a net compressive stress vector in the channel direction stress in PMOS active region 126. The differing stress imparting characteristics of stressors 200 and 202 may be controlled by altering the nitrogen composition of the two structures.

As depicted in FIG. 8, semiconductor integrated circuit 100 includes an NMOS transistor 110 and a PMOS transistor 120. NMOS transistor 110 includes source/drain implant regions 184, 192 that are formed in a crystalline or near crystalline silicon. PMOS source/drain structures 190 and 192 are formed in an amorphous silicon region 162. By creating amorphized silicon in the PMOS selectively, the stress characteristics of the transistors of integrated circuit 100 are customized for optimum PMOS and NMOS carrier mobility. Specifically, amorphizing the PMOS active region 126 causes uniaxial relaxation of the tensile stress in the PMOS transistor channel. Conversely, preventing amorphization of the NMOS channel region maintains the desirable channel direction tensile stress component in the NMOS transistor channel.

Turning now to FIG. 9 through FIG. 12, a processing sequence is depicted that is additionally beneficial in creating a compressive stress component in the channel direction of the PMOS devices. In one embodiment, the depicted processing sequence may be substituted for the processing depicted in FIG. 3 described above. Following the first PMOS amorphizing implant 140 depicted in FIG. 2, photoresist mask 130 is stripped and replaced with a hard mask (not depicted) over the NMOS devices. Alternatively, a hard mask may be used in lieu of a photoresist mask 130 for masking the NMOS regions during the first amorphizing implant and during the processing in FIG. 9 through FIG. 12.

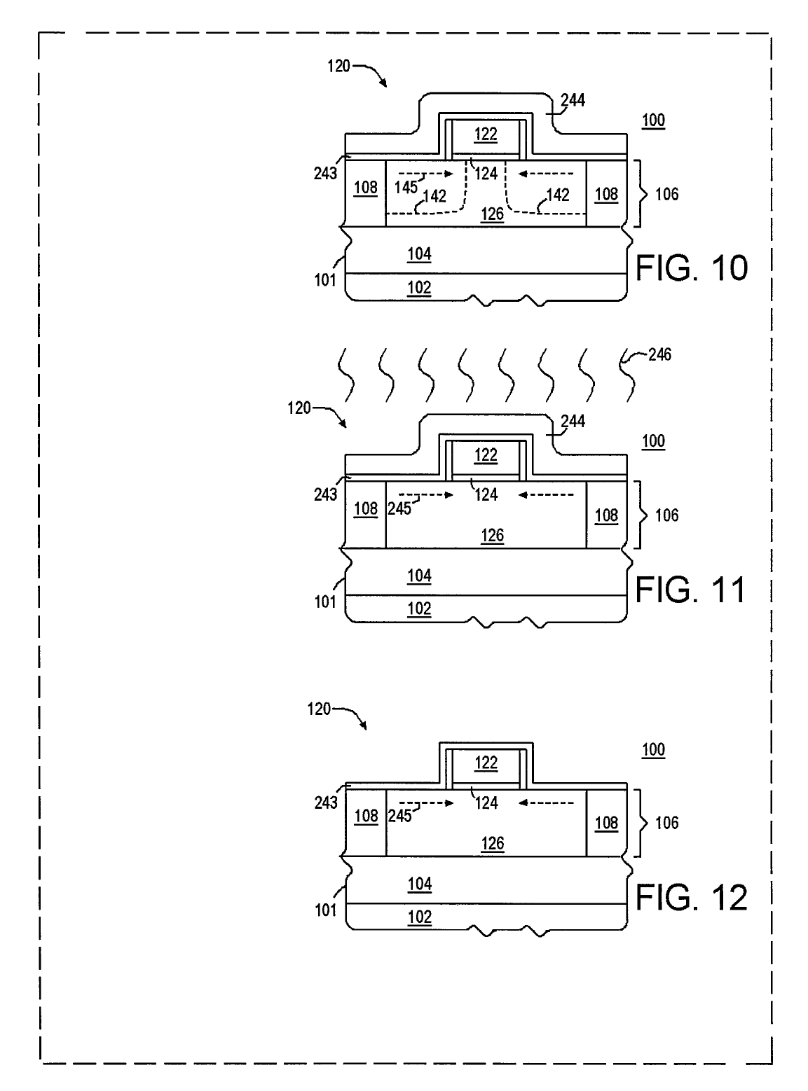

As depicted in FIG. 9, a thin (e.g., less than approximately 10 nm) pad oxide 243 is deposited overlying PMOS active region 126. In FIG. 10, a sacrificial compressive stressor 244 is deposited on pad oxide 243 overlying active region 126 and gate electrode 122. Silicon nitride provides a suitable material for sacrificial compressive stressor 244 where the compressive influence of sacrificial compressive stressor 244 is determined in part by its composition with higher concentrations of nitrogen producing a greater compressive stress effect.

As depicted in FIG. 11, an anneal 246 is performed with sacrificial compressive stressor 244 in place as deposited overlying PMOS active region 126. Anneal 246 is preferably of sufficient time and temperature (e.g., 70020 C. for 30 minutes) to recrystallize the amorphous silicon region 142 (as seen in FIG. 10). Because sacrificial compressive stressor 244 remains in place during the anneal, the compressive stress element denoted by stress vectors 245 in the channel direction of PMOS active region 126 remains as well. Moreover, it is theorized that strained semiconductors such as PMOS active region is characterized by a “memory” effect in which, for example, a stress component imparted to a substrate by the presence of an external stressor remains in the substrate even after the stressor is removed. Thus, as depicted in FIG. 12, compressive stress remains in PMOS active region 126, as indicated by the continuing presence of vectors 245 in PMOS active region 126, even after sacrificial compressive stressor 244 has been removed. Any hard mask overlying NMOS regions 116 may also be removed contemporaneously with the removal of sacrificial compressive stressor 244. The processing sequence depicted in FIG. 9 through FIG. 12 is thus suitable for creating compressive stress in a channel direction of a PMOS transistor that was under biaxial tensile stress from the starting material.

In the foregoing specification, the invention has been described with reference to specific embodiments. However, one of ordinary skill in the art appreciates that various modifications and changes can be made without departing from the scope of the present invention as set forth in the claims below. For example, although the depicted embodiments are illustrated in the context of a transistor having a single gate, strain engineering as described herein may be extended to multiple gate devices such as floating gate devices and other nonvolatile cell transistors. Accordingly, the specification and figures are to be regarded in an illustrative rather than a restrictive sense, and all such modifications are intended to be included within the scope of present invention.

Benefits, other advantages, and solutions to problems have been described above with regard to specific embodiments. However, the benefits, advantages, solutions to problems, and any element(s) that may cause any benefit, advantage, or solution to occur or become more pronounced are not to be construed as a critical, required, or essential feature or element of any or all the claims. As used herein, the terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus.

1. A semiconductor fabrication process, comprising:
forming an NMOS gate electrode overlying a crystalline, biaxially strained silicon on insulator NMOS active region and forming a PMOS gate electrode overlying a crystalline, biaxially strained silicon on insulator PMOS active region;
amorphizing a source/drain region of said PMOS active region to reduce a width direction stress component in said PMOS active region;
annealing the PMOS active region to re-crystallize said PMOS source/drain region;
re-amorphizing said source/drain region of said PMOS active region;
performing a PMOS source/drain implant in said re-amorphized PMOS source/drain region; and
performing an NMOS source/drain implant in an NMOS source/drain region of said NMOS active region.

2. A semiconductor fabrication process, comprising:
forming an NMOS gate electrode overlying an NMOS active region of a semiconductor wafer substrate and forming a PMOS gate electrode overlying a PMOS active region of the substrate;
amorphizing a source/drain region of the PMOS active region;
performing a PMOS source/drain implant in the amorphous PMOS source/drain region; and
performing an NMOS source/drain implant in a source/drain region of the NMOS active region.

3. The method of claim 2, wherein, prior to said amorphizing, the NMOS active region and the PMOS active region exhibit biaxial tensile stress.

4. The method of claim 2, wherein amorphizing the PMOS source/drain region comprises forming a mask overlying the NMOS active region and implanting a species selected from the group consisting of Ge, Ga, and Xe into the PMOS active region using the PMOS gate electrode as an implant mask in the PMOS active region.

5. The method of claim 2, further comprising forming a compressive stressor overlying the PMOS active region after performing the PMOS source/drain implant.

6. The method of claim 2, wherein amorphizing said PMOS source/region comprises performing a first PMOS amorphizing implant.

7. The method of claim 6, further comprising, annealing the wafer following the first amorphizing implant to recrystallize the amorphous PMOS source/drain region.

8. The method of claim 7, wherein performing said PMOS source/drain implant in the amorphous source/drain region includes:
performing a second PMOS amorphizing implant following said anneal to re-amorphize the PMOS source/drain region; and
performing the PMOS source/drain implant following said second PMOS amorphizing implant.

9. The method of claim 8, wherein performing said PMOS source/drain implant includes:
performing a PMOS halo implant;
performing a PMOS source/drain extension implant;
forming extension spacers adjacent sidewalls of the PMOS gate electrode; and
performing a PMOS deep source/drain implant.

10. The method of claim 6, further comprising, following said first PMOS amorphizing implant:
forming a sacrificial compressive stressor overlying said PMOS gate electrode and active region;
annealing said wafer to recrystallize said amorphous source/drain region; and
removing said sacrificial compressive stressor.

11. The method of claim 2, wherein performing said NMOS implant comprises performing said NMOS implant in a crystalline NMOS source/drain region.

12. The method of claim 2, wherein performing said NMOS source/drain implant comprises performing an NMOS amorphizing implant before creating said NMOS source/drain region.

13. The method of claim 12, wherein an implant energy of said NMOS amorphizing implant is no greater than 20 keV.

14. A semiconductor fabrication process, comprising:
forming an NMOS gate electrode overlying a biaxially strained NMOS active region and forming a PMOS gate electrode overlying a biaxially strained PMOS active region;
reducing a channel direction tensile stress component in the PMOS active region while maintaining a channel direction tensile stress component in the NMOS active region; and
after said reducing, forming PMOS source/drain region in said PMOS active region and forming NMOS source/drain regions in said NMOS active region.

15. The method of claim 14, wherein said reducing of said channel direction tensile stress component comprises:
forming a mask overlying said NMOS active region; and
performing a first PMOS amorphizing implant in a source/drain region of said PMOS active region.

16. The method of claim 15, wherein an implant species for said first PMOS amorphizing implant is selected from the group of species consisting of Ge, Ga, and Xe, an implant energy is approximately 40 keV and an implant does is approximately 1×10¹⁵ cm⁻².

17. The method of claim 15, wherein performing said PMOS source/drain implant includes;
after said first PMOS amorphizing implant, annealing said PMOS active region to recrystallize said PMOS active region;
performing a second PMOS amorphizing implant in said PMOS source/drain regions; and
performing a PMOS halo implant and a PMOS source/drain extension implant.

18. The method of claim 17, further comprising, after said first amorphizing implant and before said annealing, depositing a compressive dielectric layer overlying the PMOS gate electrode and the PMOS active region.

19. The method of claim 18, further comprising, after said annealing, removing the compressive dielectric layer before performing said second PMOS amorphizing implant.

20. The method of claim 19, wherein depositing said compressive dielectric layer comprises depositing compressive silicon nitride.
